(19) United States
(12) Patent Application Publication
(10) Pub. No.: US 2026/0018134 A1
(43) Pub. Date: Jan. 15, 2026

(54) Display Apparatus

(71) Applicant: LG Display Co., Ltd., Seoul (KR)

(72) Inventors: Intae Ko, Paju-si (KR); Hyunjik Bae, Paju-si (KR)

(21) Appl. No.: 19/220,001

(22) Filed: May 27, 2025

(30) Foreign Application Priority Data
Jul. 15, 2024 (KR) 10-2024-0093031

(51) Int. Cl. G09G 3/3266; H10K 59/121; H10K 59/122; H10K 59/131

(52) U.S. Cl. CPC G09G 3/3266; H10K 59/1213; H10K 59/122; H10K 59/1315; G09G 2300/0426

(57) ABSTRACT

A display apparatus may include a substrate including a display area and a non-display area disposed around the display area, a light-emitting part disposed on the substrate in the display area, a pixel transistor disposed on the substrate in the display area, a gate driving unit disposed on the substrate in the non-display area and connected to the pixel transistor, and a low-potential voltage line disposed on the substrate in the non-display area and connected to the light-emitting part, wherein the gate driving unit and the low-potential voltage line overlap each other in the non-display area.

### CROSS REFERENCE TO RELATED APPLICATION

The present application claims priority to Republic of Korea Patent Application No. 10-2024-0093031, filed on Jul. 15, 2024, which is hereby incorporated by reference in its entirety.

### BACKGROUND

### Field of Technology

The present specification relates to a display apparatus.

### Description of the Related Art

As the information society develops, various demands for display apparatuses for displaying images are increasing, and various types of display apparatuses, such as a liquid crystal display (LCD) apparatus and an organic light emitting diode (OLED) display apparatus, are being utilized.

Among the display apparatuses, there is an advantage in that the OLED display apparatus as the self-luminous type has a wider viewing angle and a high contrast ratio and is lighter and thinner and has less power consumption than the LCD apparatus because it does not require a separate backlight. In addition, there is an advantage in that the OLED display apparatus can drive at a low voltage, have a fast response time, and especially have the inexpensive manufacturing cost.

The OLED display apparatus can also be applied to display apparatuses mounted on vehicles. Among display apparatuses installed on a vehicle, display apparatuses in front of a driver's seat and a front passenger's seat need to limit a viewing angle of a driver according to driving situations of the driver. The display apparatus needs to limit a viewing angle according to a user's needs for privacy and information protection.

### SUMMARY

The present specification is directed to providing a display apparatus having a design with improved aesthetic feeling.

The present specification is also directed to providing a display apparatus in which it is possible to minimize a bezel.

The present specification is also directed to providing a display apparatus in which resistance of a line does not increase even when a bezel is reduced.

The present specification is also directed to providing a display apparatus in which it is possible to optimize a process with a minimized bezel of the display apparatus, thereby suppressing or preventing an increase in production energy.

Objects of the present specification are not limited to the above-described objects, and other technical objects may be inferred from the following embodiments.

According to one embodiment of the present specification, there is provided a display apparatus including a substrate including a display area and a non-display area disposed around the display area, a light-emitting part disposed on the substrate in the display area, a pixel transistor disposed on the substrate in the display area, a gate driving unit disposed on the substrate in the non-display area and connected to the pixel transistor, and a low-potential voltage line disposed on the substrate in the non-display area and connected to the light-emitting part, wherein the gate driving unit and the low-potential voltage line overlap each other in the non-display area.

According to another embodiment of the present specification, there is provided a display apparatus including a substrate including a display area in which a plurality of sub-pixels are disposed, and a non-display area disposed around the display area, a low-potential voltage line disposed in the non-display area, and a pad area disposed in the non-display area, wherein the non-display area includes a first non-display area disposed under the display area, and a second non-display area disposed at left, right, and upper sides of the display area, and the low-potential voltage line includes a first low-potential voltage line formed of a first conductive layer and disposed in the first non-display area, and a second low-potential voltage line formed of a second conductive layer different from the first conductive layer and disposed in the second non-display area.

Detailed matters of other embodiments are included in the detailed description and accompanying drawings.

According to the embodiments of the present specification, it is possible to provide the display apparatus with improved aesthetic feeling.

According to the embodiments of the present specification, it is possible to minimize the bezel.

According to the embodiments of the present specification, the resistance of the line does not increase even when the bezel is reduced.

According to the embodiments of the present specification, it is possible to optimize the process with the minimized bezel of the display apparatus, thereby suppressing or preventing an increase in production energy.

However, effects obtainable from the present specification are not limited to the above-described effects, and other effects that are not mentioned will be able to be clearly understood by those skilled in the art to which the present specification pertains based on the following description.

### BRIEF DESCRIPTION OF THE DRAWINGS

FIG. 1 is a plan view of a display apparatus according to one embodiment.

FIG. 2 is an enlarged view of area Q1 in FIG. 1 according to one embodiment.

FIG. 3 is a view illustrating a display panel of FIG. 2 according to one embodiment.

FIG. 4 is a plan view illustrating a pixel arrangement of a display panel according to one embodiment.

FIG. 5 is a cross-sectional view along line V-V′ in FIG. 4 according to one embodiment.

FIG. 6 is a cross-sectional view of a touch part of FIG. 5 taken at a different angle according to one embodiment.

FIG. 7 is a plan view of a display panel according to one embodiment.

FIG. 8 is a cross-sectional view along line VIII-VIII′ in FIG. 7 according to one embodiment.

FIG. 9 is a cross-sectional view along line A-A′ in FIG. 1 according to one embodiment.

FIG. 10 is a cross-sectional view along line B-B′ in FIG. 3 according to one embodiment.

FIG. 11 is a cross-sectional view along line C-C′ in FIG. 3 according to one embodiment.

### DETAILED DESCRIPTION

Hereinafter, embodiments will be described with reference to the accompanying drawings. In the specification, when a first component (or an area, a layer, a portion, etc.) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

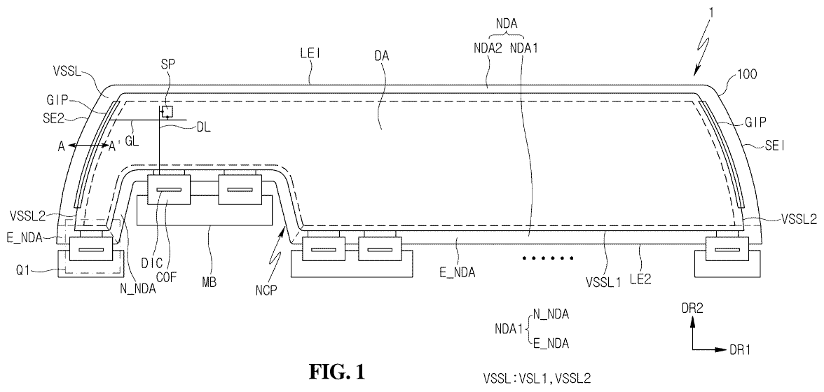

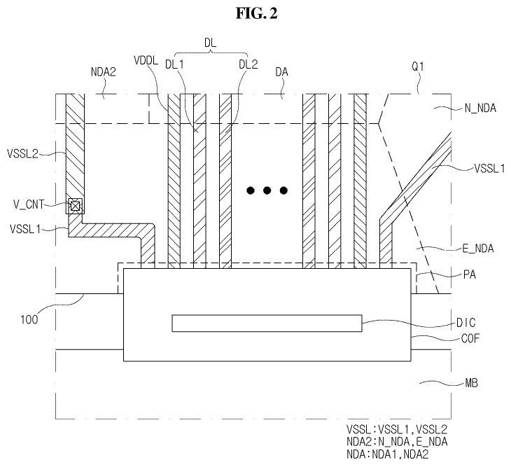

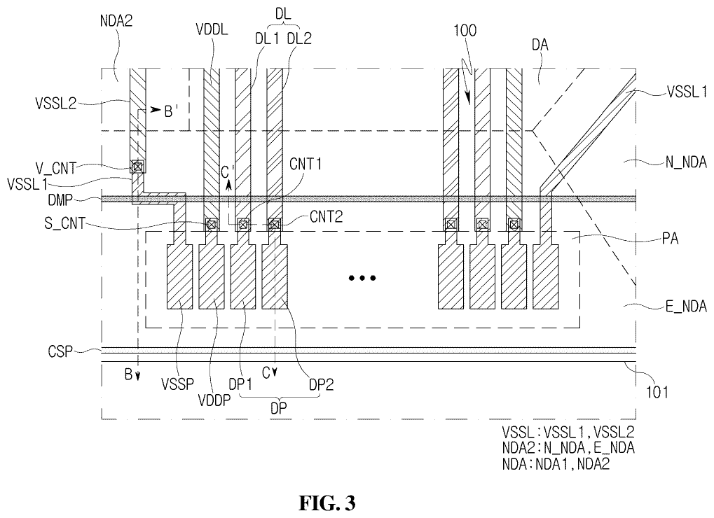

FIG. 1 is a plan view of a display apparatus according to one embodiment. FIG. 2 is an enlarged view of area Q1 in FIG. 1 according to one embodiment. FIG. 3 is a view illustrating only a display panel of FIG. 2 according to one embodiment.

FIG. 3 is a view of FIG. 2 from which a flexible film COF, a main board MB, and a drive integrated circuit (IC) DIC are omitted except for the display panel 100. In FIG. 3, for convenience of description, ratios between components are adjusted.

Referring to FIGS. 1 to 3, a display apparatus 1 may be an apparatus including both a display function for displaying a video and a touch sensing function for sensing touch of a user, but is not limited thereto. For example, the display apparatus 1 may include only one of the display function of displaying an image and the touch sensing function of sensing a user's touch.

The display apparatus 1 may be an electroluminescent display apparatus or a micro light-emitting diode display apparatus that includes a touch sensor. The electroluminescent display apparatus including the touch sensor may be an organic light-emitting diode (OLED) display apparatus, a quantum-dot light-emitting diode display apparatus, or an inorganic light-emitting diode display apparatus.

The display apparatus 1 according to the present embodiment may be a vehicle display apparatus, but is not limited thereto. For example, the description of the display apparatus 1 may be applied without limitation to the type of the apparatus as long as a display apparatus is an apparatus including a display function.

When the display apparatus 1 according to the present embodiment is a vehicle display apparatus, the display apparatus 1 may include a function of manipulating at least some of various functions of a vehicle, a function of displaying various pieces of information about the vehicle, etc.

When the display apparatus 1 according to the present embodiment is a vehicle display apparatus, the display apparatus 1 may be disposed on a dashboard of a vehicle. The display apparatus 1 may be disposed across a driver's seat and a front passenger's seat that are disposed at front seats of a vehicle, but is not limited thereto. Both a driver in the driver's seat and a passenger in the front passenger's seat can use the display apparatus 1.

The display apparatus 1 may include a display panel 100. The display panel 100 may include a display area DA and a non-display area NDA.

The display area DA may be an area in which light is emitted to the outside to display a screen. The display area DA may further include a function of sensing a user's touch. In this case, the display area DA may correspond to a touch sensing area, but is not limited thereto.

The display area DA may correspond to the shape of the display panel 100, but is not limited thereto.

A plurality of sub-pixels SP (or pixels) may be disposed in the display area DA. The sub-pixels may be repeatedly disposed in a first direction DR1 and a second direction DR2.

The non-display area NDA may be an area in which light is not emitted to the outside so as not to display a screen. The non-display area NDA may be located around the display area DA. The non-display area NDA may surround the display area DA, but the embodiments of the present specification are not limited thereto. A bezel area of the display apparatus 1 may be defined by the non-display area NDA, but the embodiments of the present specification are not limited thereto.

The display panel 100 may be a rigid display panel, but is not limited thereto. The display panel 100 may be a flexible display panel of which shape may be deformed, such as a foldable, bendable, rollable, or stretchable display panel.

The display panel 100 may include a first long edge LE1, a second long edge LE2, a first short edge SE1, and a second short edge SE2 that form an edge of the display panel 100.

The first long edge LE1 and the second long edge LE2 may extend in a first direction DR1, and the first short edge SEI and the second short edge SE2 may extend in a direction between the first direction DR1 and a second direction DR2. The first long edge LE1 and the second long edge LE2 may have both ends connected through the first short edge SE1 and the second short edge SE2.

The first long edge LE1 may be disposed at one side of the second long edge LE2 in the second direction DR2. The first long edge LE1 and the second long edge LE2 may extend in parallel, but are not limited thereto.

A length of the first long edge LE1 may be shorter than a length of the second long edge LE2. Accordingly, the first short edge SE1 and the second short edge SE2 may extend in an intersecting direction, but are not limited thereto.

The first direction DR1 and the second direction DR2 may be directions intersecting each other. The first direction DR1 and the second direction DR2 may be orthogonal, but are not limited thereto. The first direction DR1 and the second direction DR2 are provided to clarify the description of the invention, the first direction DR1 and the second direction DR2 are relative, and the embodiments of the present specification are not limited thereto.

In a plan view, the first long edge LE1 may be disposed above the display area DA, and the second long edge LE2 may be disposed under the display area DA.

In a plan view, the first short edge SE1 may be disposed at the right side of the display area DA, and the second short edge SE2 may be disposed at the left side of the display area DA.

The display panel 100 may include a curved notch NCP. The notch NCP may be formed at the second long edge LE2, but is not limited thereto. That is, the second long edge LE2 may entirely extend in the first direction DR1, but may include the notch NCP that is curved toward the first long edge LE1.

Since the notch NCP is disposed, components, such as a handle of a driver's seat, may be disposed on the corresponding portion to maximize the display area DA capable of displaying the screen, thereby improving a user's convenience and improving aesthetic feeling.

The non-display area NDA may include a first non-display area NDA1 disposed along the second long edge LE2, and a second non-display area NDA2 disposed along the first long edge LE1, the first short edge SE1, and the second short edge SE2. The first non-display area NDA1 may be disposed along the second long edge LE2 including the curved notch NCP.

In a plan view, the first non-display area NDA1 may be disposed at a lower side (bottom) of the display area DA, and the second non-display area NDA2 may be disposed at the left, right, and upper (top) sides of the display area DA, but the embodiments of the present specification area not limited thereto.

The first non-display area NDA1 may include a notch non-display area N_NDA disposed around the notch NCP, and an extension non-display area E_NDA disposed around the notch non-display area N_NDA.

The extension non-display area E_NDA may extend from the notch non-display area N_NDA in the first direction DR1. The extension non-display area E_NDA may be disposed between the notch non-display area N_NDA and the second non-display area NDA2. The extension non-display area E_NDA may connect the notch non-display area N_NDA to the second non-display area NDA2.

The first non-display area NDA1 may be disposed at the other side of the display area DA in the second direction DR2. The second non-display area NDA2 may be disposed at one side and the other side of the display area DA in the first direction DR1 and disposed at one side of the display area DA in the second direction DR2.

The display apparatus 1 may further include a pad area PA, a gate driving unit GIP (e.g. a circuit), a main board MB, a flexible film COF, a drive IC DIC, a gate line GL, a data line DL, a low-potential voltage line VSSL, and a high-potential voltage line VDDL.

The pad area PA may overlap the flexible film COF. The pad area PA may be attached to the flexible film COF. That is, the display panel 100 and the flexible film COF may be attached through the pad area PA.

The pad area PA may be disposed in the non-display area NDA. The pad area PA may be disposed in the first non-display area NDA1. The pad area PA may be disposed in each of the notch non-display area N_NDA and the extension non-display area E_NDA.

The pad area PA may include a plurality of pads. The pad area PA may include a low-potential voltage pad VSSP, a high-potential voltage pad VDDP, a first data pad DP1, and a second data pad DP2. The low-potential voltage pad VSSP, the high-potential voltage pad VDDP, the first data pad DP1, and the second data pad DP2 may be disposed in the pad area PA.

However, the embodiments of the present specification are not limited thereto, and the pad area PA disposed in an area that overlaps the flexible films COFs disposed at both ends among the flexible films COFs disposed along the non-display area NDA may further include a gate control pad (not illustrated). The gate control pad (not illustrated) may be connected to the gate driving unit GIP through a gate control line (not illustrated).

The gate driving unit GIP may be disposed in the non-display area NDA. The gate driving unit GIP may be disposed at at least one of one side and another side of the display area DA in the first direction DR1, but is not limited thereto. In a plan view, the gate driving unit GIP may be disposed at the left side and the other side of the display area DA.

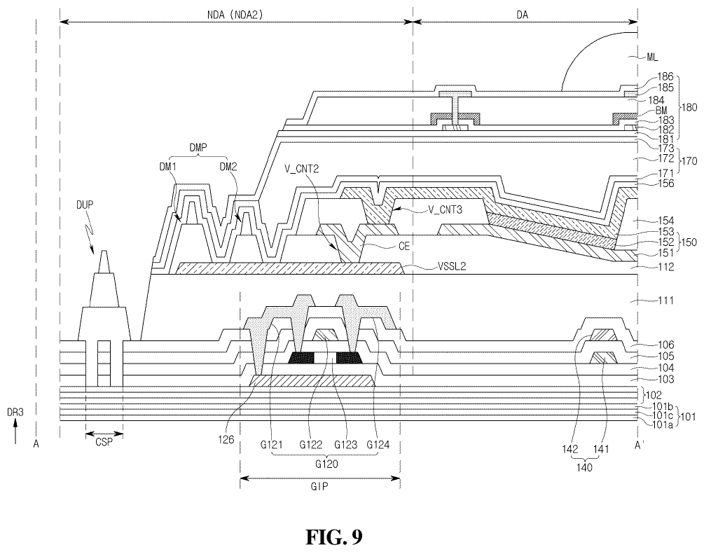

The gate driving unit GIP may include a plurality of transistors G120 (see FIG. 9, which are also referred to as gate control transistors). The gate driving unit GIP may be connected to the sub-pixel through the gate line GL. The transistors G120 (see FIG. 9) disposed in the gate driving unit GIP may be connected to a sub-pixel SP (or a pixel) through the gate line GL. The gate driving unit GIP may apply a gate signal to each sub-pixel SP (or each pixel) through the gate line GL.

The gate driving unit GIP may receive a gate control signal from the drive IC DIC through a gate control line. The gate driving unit GIP may generate a scan signal and a light-emitting signal (or a light-emitting control signal) based on the gate control signal.

The gate driving unit GIP may include a scan driver and a light-emitting signal driver. The scan driver may generate a scan signal in a row-sequential manner and supply the scan signal to the scan lines in order to drive one or more scan lines connected to each sub-pixel SP (or each pixel) row. The light-emitting signal driver may generate a light-emitting signal in a row-sequential manner and supply the light-emitting signal to light-emitting signal lines in order to drive one or more light-emitting signal lines connected to each sub-pixel SP (or each pixel) row.

The gate driving unit GIP may overlap the low-potential voltage line VSSL in the non-display area NDA. The transistor G120 (see FIG. 9) of the gate driving unit GIP may overlap the low-potential voltage line VSSL.

Accordingly, the non-display area NDA can be reduced and the bezel can also be reduced. Furthermore, high aesthetic feeling and convenience can be provided to a user.

The main board MB may be connected to the display panel 100 through the flexible film COF. The main board MB may be electrically connected to the sub-pixel SP (or the pixel) of the display area DA through the flexible film COF. The main board MB may be electrically connected to the flexible film COF. The main board MB and the flexible film COF may be electrically connected through the plurality of pads VSSP, VDDP, and DP.

The main board MB may have various types of components for supplying various signals, such as a gate control signal, a driving signal, a data signal, etc., to the drive IC DIC. The main board MB may be a printed circuit board, but is not limited thereto.

The main board MB may be connected to the display panel 100 through the flexible film COF in the first non-display area NDA1. The main board MB may be provided as a plurality of main boards along the first non-display area NDA1, but is not limited thereto. The number of main boards MB may vary according to a design.

At least one of the main boards MB may be disposed around the notch NCP and connected to the display panel 100 through the flexible film COF in the notch non-display area N_NDA.

The flexible film COF may be connected to the display panel 100 and the main board MB. The flexible film COF may be attached to each of the display panel 100 and the main board MB and electrically connected to each of the display panel 100 and the main board MB. That is, the display panel 100 and the main board MB may be electrically connected through the flexible film COF. The flexible film COF may be provided as a plurality of flexible films, but is not limited thereto.

The flexible film COF may be attached to the display panel 100 in the first non-display area NDA1. The flexible film COF may be attached to overlap the pad area PA disposed in the non-display area NDA, but is not limited thereto. The flexible film COF may be repeatedly disposed along the first non-display area NDA1. The flexible film COF may be attached to the display panel 100 across the notch non-display area N_NDA and the extension non-display area E_NDA.

A single main board MB may be electrically connected to the display panel 100 through at least one flexible film COF. For example, the main boards MB disposed at both ends among the plurality of main boards MB disposed along the first non-display area NDA1 may be electrically connected to the display panel 100 through one flexible film COF, and the remaining main boards MB may be electrically connected to the display panel 100 through two flexible films COF.

The flexible film COF may be electrically connected to the pad area PA. Accordingly, the flexible film COF may supply a gate control signal, driving signals, power voltages, data voltages, etc. to the plurality of sub-pixels SP (or the pixels) and the gate driving unit GIP that are disposed in the display area DA.

The flexible film COF may be a flexible insulating film. The flexible film COF may include, for example, polycarbonate, polyethylene terephthalate, polyimide, polyamide, polyester, polyacrylate, polymethyl methacrylate, etc., but is not limited thereto.

The drive IC DIC may be mounted on the flexible film COF. The drive IC DIC may be disposed by a method of a chip on glass, a chip on film, a tape carrier package, etc. according to a mounting method. In the present disclosure, the drive IC DIC is described as being mounted on the flexible film COF by the chip on film method, but is not limited thereto.

The drive IC DIC may drive the display apparatus 1. The drive IC DIC may process data signals for displaying an image, various driving signals for processing the data signals, etc. The drive IC DIC may include a gate driver IC, a data driver IC, etc.

The gate line GL may extend from the gate driving unit GIP and may be connected to the sub-pixel SP (or the pixel). The gate line GL may electrically connect the gate driving unit GIP to the sub-pixel SP (or the pixel). The gate line GL may apply a gate signal to each sub-pixel SP (or the pixel) from the gate driving unit GIP.

Although not illustrated, the display panel 100 may further include the gate control line (not illustrated). The gate control line (not illustrated) may be disposed in the non-display area NDA. The gate control line (not illustrated) may extend from the pad area PA to the gate driving unit GIP and may be electrically connected to the gate driving unit GIP.

The gate control line (not illustrated) may apply the gate control signal to the gate driving unit GIP. The gate control signal may be transmitted from the main board MB or the drive IC DIC. The gate control line (not illustrated) may electrically connect the gate driving unit GIP to the main board MB or the drive IC DIC.

The gate control line (not illustrated) may be electrically connected to the flexible film COF disposed at both ends among the plurality of flexible films COF connected to the display panel 100 along the first non-display area NDA1. The gate control line (not illustrated) may be disposed at an outermost edge among a plurality of lines connected to one flexible film COF, but is not limited thereto.

The data line DL may extend from the pad area PA and may be connected to the sub-pixel SP (or the pixel) of the display area DA. The data line DL may apply a data signal to each sub-pixel SP (or each pixel). The data signal may be applied from the main board MB or the drive IC DIC. The data line DL may electrically connect the sub-pixel SP (or the pixel) to the main board MB or the drive IC DIC.

The data line DL may include a first data line DL1 and a second data line DL2. The data line DL may be connected to the data pads DPI and DP2. The first data line DL1 may be electrically connected in contact with the first data pad DP1 through a first data contact hole CNT1. The second data line DL2 may be electrically connected in contact with the second data pad DP2 through a second data contact hole CNT2.

The low-potential voltage line VSSL may be disposed in the non-display area NDA to surround the display area DA. The low-potential voltage line VSSL may be disposed in the non-display area NDA with the display area DA and the gate driving unit GIP interposed therebetween. That is, the gate driving unit GIP may be disposed between the display area DA and the low-potential voltage line VSSL.

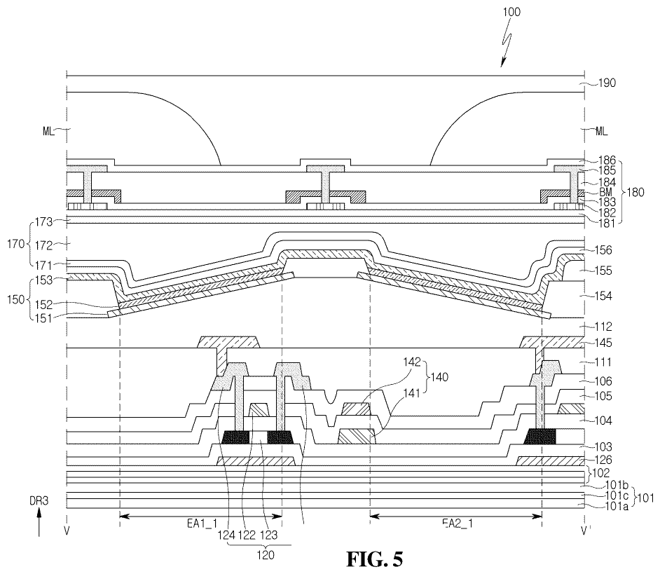

The low-potential voltage line VSSL may apply a low-potential voltage to the sub-pixel SP (or the pixel). The low-potential voltage line VSSL may be electrically connected to a cathode electrode 153 (see FIG. 5) of the sub-pixel SP (or the pixel) to apply a low-potential voltage.

The low-potential voltage line VSSL may be connected to the pad area PA. The low-potential voltage line VSSL may be physically connected to the low-potential voltage pad VSSP and electrically connected to the low-potential voltage pad VSSP.

The low-potential voltage line VSSL may overlap the gate driving unit GIP. The low-potential voltage line VSSL may overlap the transistor G120 (see FIG. 9) of the gate driving unit GIP.

The low-potential voltage line VSSL may include a first low-potential voltage line VSSL1 and a second low-potential voltage line VSSL2 that are disposed on different layers.

The first low-potential voltage line VSSL1 may be disposed in the first non-display area NDA1, and the second low-potential voltage line VSSL2 may be disposed in the second non-display area NDA2.

The first low-potential voltage line VSSL1 may be disposed along the first non-display area NDA1 and disposed at the other side of the display area DA in the second direction DR2. In a plan view, the first low-potential voltage line VSSL1 may be disposed at a lower side (bottom) of the display area DA.

The first low-potential voltage line VSSL1 may be disposed across the notch non-display area N_NDA and the extension non-display area E_NDA.

The second low-potential voltage line VSSL2 may be disposed along the second non-display area NDA2, disposed at one side and the other side of the display area DA in the first direction DR1, and the other side, and disposed at one side of the display area DA in the second direction DR2. In a plan view, the second low-potential voltage line VSSL2 may be disposed at left, right, and upper sides (top) of the display area DA.

The first low-potential voltage line VSSL1 may be electrically connected in contact with the second low-potential voltage line VSSL2 through a low-potential contact hole V_CNT around both ends. Accordingly, the first low-potential voltage line VSSL1 and the second low-potential voltage line VSSL2 may be disposed to surround the display area DA, but are not limited thereto.

The first low-potential voltage line VSSL1 may extend from the pad area PA. The first low-potential voltage line VSSL1 may be electrically connected to the low-potential voltage pad VSSP. The first low-potential voltage line VSSL1 and the low-potential voltage pad VSSP may be integrally formed, but are not limited thereto.

The second low-potential voltage line VSSL2 may overlap the gate driving unit GIP. The second low-potential voltage line VSSL2 may overlap the transistor G120 (see FIG. 9) of the gate driving unit GIP.

Accordingly, an area of the second low-potential voltage line VSSL2 and an area of the gate driving unit GIP in the second non-display area NDA2 may overlap each other, and an area of the second non-display area NDA2 can be reduced.

A bezel area of the display apparatus 1 can be reduced, and even when the bezel area is reduced, a thickness of the second low-potential voltage line VSSL2 cannot be reduced. Accordingly, even when the bezel area is reduced, it is possible to suppress or prevent an increase in resistance of the second low-potential voltage line VSSL2.

Furthermore, it is possible to minimize the bezel, thereby providing higher aesthetic feeling and use convenience to a user.

The high-potential voltage line VDDL may be disposed between the display area DA and the low-potential voltage line VSSL. The high-potential voltage line VDDL may apply a high-potential voltage to the sub-pixel SP (or the pixel). The high-potential voltage line VDDL may be electrically connected to an anode electrode 151 (see FIG. 5) of the sub-pixel SP (or the pixel) to apply a high-potential voltage.

The high-potential voltage line VDDL may be connected to the pad area PA. The high-potential voltage line VDDL may be physically connected to the high-potential voltage pad VDDP and electrically connected to the high-potential voltage pad VDDP.

The high-potential voltage line VDDL may contact the high-potential voltage pad VDDP by a high-potential contact hole S_CNT. However, the embodiments of the present specification are not limited thereto. However, the high-potential voltage line VDDL may be formed integrally with the high-potential voltage pad VDDP. In this case, the high-potential voltage line VDDL may include the same material as the high-potential voltage pad VDDP, and the high-potential voltage line VDDL and the high-potential voltage pad VDDP are formed together by the same mask process.

The display apparatus 1 may further include a dam part DMP. The dam part DMP may be disposed in the non-display area NDA. The dam part DMP may be disposed to surround the display area DA, but is not limited thereto. At least a part of the dam part DMP may be disposed to overlap the low-potential voltage line VSSL. The dam part DMP may be disposed between the display area DA and the pad area PA in the first non-display area NDA1.

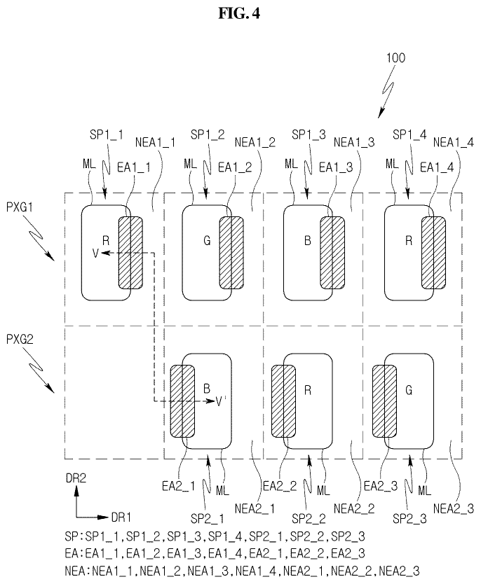

FIG. 4 is a plan view illustrating a pixel arrangement of a display panel according to one embodiment. The plan view of FIG. 4 is an enlarged view illustrating a part of the display area DA in which the pixels PX are disposed.

Referring to FIG. 4, the display panel 100 may include a first pixel group PXG1 and a second pixel group PXG2.

Each of the first pixel group PXG1 and the second pixel group PXG2 may be disposed repeatedly in the first direction DR1. The first pixel group PXG1 and the second pixel group PXG2 may be disposed alternately and repeatedly in the second direction DR2.

The sub-pixel SP may include a 1_1 sub-pixel SP1_1, a 1_2 sub-pixel SP1_2, a 1_3 sub-pixel SP1_3, a 1_4 sub-pixel SP1_4, a 2_1 sub-pixel SP2_1, a 2_2 sub-pixel SP2_2, and a 2_3 sub-pixel SP2_3.

The first pixel group PXG1 may include the 1_1 sub-pixel SP1_1, the 1_2 sub-pixel SP1_2, the 1_3 sub-pixel SP1_3, and the 1_4 sub-pixel SP1_4. The 1_1 sub-pixel SP1_1, the 1_2 sub-pixel SP1_2, the 1_3 sub-pixel SP1_3, and the 1_4 sub-pixel SP1_4 may be disposed in a row in the first direction.

The 1_1 sub-pixel SP1_1 may emit red (R) light, the 1_2 sub-pixel SP1_2 may emit green (G) light, the 1_3 sub-pixel SP1_3 may emit blue (B) light, and the 1_4 sub-pixel SP1_4 may emit red (R) light.

The 1_1 sub-pixel SP1_1, the 1_2 sub-pixel SP1_2, the 1_3 sub-pixel SP1_3, and the 1_4 sub-pixel SP1_4 may include light-emitting areas EA1_1, EA1_2, EA1_3, and EA1_4, and non-light-emitting areas NEA1_1, NEA1_2, NEA1_3, and NEA1_4 disposed around the light-emitting areas EA1_1, EA1_2, EA1_3, and EA1_4, respectively.

The 1_1 sub-pixel SP1_1 may include a 1_1 light-emitting area EA1_1, and a 1_1 non-light-emitting area NEA1_1 disposed around the 1_1 light-emitting area EA1_1.

The 1_2 sub-pixel SP1_2 may include a 1_2 light-emitting area EA1_2, and a 1_2 non-light-emitting area NEA1_2 disposed around the 1_2 light-emitting area EA1_2.

The 1_3 sub-pixel SP1_3 may include a 1_3 light-emitting area EA1_3, and a 1_3 non-light-emitting area NEA1_3 disposed around the 1_3 light-emitting area EA1_3.

The 1_4 sub-pixel SP1_4 may include a 1_4 light-emitting area EA1_4 and a 1_4 non-light-emitting area NEA1_4 disposed around the 1_4 light-emitting area EA1_4.

The second pixel group PXG2 may include the 2_1 sub-pixel SP2_1, the 2_2 sub-pixel SP2_2, and the 2_3 sub-pixel SP2_3. The 2_1 sub-pixel SP2_1, the 2_2 sub-pixel SP2_2, and the 2_3 sub-pixel SP2_3 may be disposed in a row in the second direction.

The 2_1 sub-pixel SP2_1 may emit blue (B) light, the 2_2 sub-pixel SP2_2 may emit red (R) light, and the 2_3 sub-pixel SP2_3 may emit green (G) light.

The 2-1 sub-pixel SP2_1, the 2_2 sub-pixel SP2_2, and the 2_3 sub-pixel SP2_3 may include light-emitting areas EA2_1, EA2_2, and EA2_3, and non-light-emitting areas NEA2_1, NEA2_2, and NEA2_3 disposed around the light-emitting areas EA2_1, EA2_2, and EA2_3.

The 2_1 sub-pixel SP2_1 may include a 2_1 light-emitting area EA2_1, and a 2_1 non-light-emitting area NEA2_1 disposed around the 2_1 light-emitting area EA2_1.

The 2_2 sub-pixel SP2_2 may include a 2_2 light-emitting area EA2_2, and a 2_2 non-light-emitting area NEA2_2 disposed around the 2_2 light-emitting area EA2_2.

The 2_3 sub-pixel SP2_3 may include a 2_3 light-emitting area EA2_3, and a 2_3 non-light-emitting area NEA2_3 disposed around the 2_3 light-emitting area EA2_3.

In a plan view, no sub-pixel may be disposed below (at the other side in the second direction DR2 of) the 1_1 sub-pixel SP1_1.

In a plan view, the 2_1 sub-pixel SP2_1 may be disposed below (at the other side in the second direction DR2 of) the 1_2 sub-pixel SP1_2.

In a plan view, the 2_2 sub-pixel SP2_2 may be disposed below (at the other side in the second direction DR2 of) the 1_3 sub-pixel SP1_3.

In a plan view, the 2_3 sub-pixel SP2_3 may be disposed below (at the other side in the second direction DR2) the 1_4 sub-pixel SP1_4.

The sub-pixel SP (see FIG. 1) illustrated in FIG. 1 may refer to one of the 1_1 sub-pixel SP1_1, the 1_2 sub-pixel SP1_2, the 1_3 sub-pixel SP1_3, the 1_4 sub-pixel SP1_4, the 2_1 sub-pixel SP2_1, the 2_2 sub-pixel SP2_2, and the 2_3 sub-pixel SP2_3.

A microlens ML may be disposed on the 1_1 sub-pixel SP1_1, the 1_2 sub-pixel SP1_2, the 1_3 sub-pixel SP1_3, the 1_4 sub-pixel SP1_4, the 2_1 sub-pixel SP2_1, the 2_2 sub-pixel SP2_2, and the 2_3 sub-pixel SP2_3. The microlens ML may be disposed in each sub-pixel SP (SP1_1, SP1_2, SP1_3, SP1_4, SP2_1, SP2_2, or SP2_3).

One microlens ML is illustrated as being disposed in each sub-pixel SP, but the embodiments of the present specification are not limited thereto. For example, according to a design of each sub-pixel SP, the microlens ML disposed in each sub-pixel SP may be provided as two or more microlenses. When an opening (the light-emitting areas EA) formed in one sub-pixel SP is provided as a plurality of openings, the microlens ML may be disposed in each opening, or a plurality of microlenses ML may be disposed in one opening.

Each sub-pixel SP (SP1_1, SP1_2, SP1_3, SP1_4, SP2_1, SP2_2, or SP2_3) may include the light-emitting area EA (EA1_1, EA1_2, EA1_3, EA1_4, EA2_1, EA2_2, or EA2_3) and the non-light-emitting area NEA (NEA1_1, NEA1_2, NEA1_3, NEA1_4, NEA2_1, NEA2_2, or NEA2_3) disposed around the light-emitting area EA.

Hereinafter, a cross-sectional structure of the display area DA of the display panel 100 including the sub-pixel SP (SP1_1, SP1_2, SP1_3, SP1_4, SP2_1, SP2_2, and SP2_3) will be described with reference to FIG. 5.

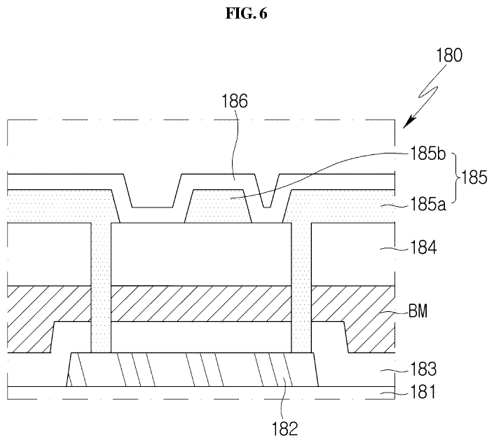

FIG. 5 is a cross-sectional view along line V-V′ in FIG. 4 according to one embodiment. FIG. 6 is a cross-sectional view of a touch part of FIG. 5 taken at a different angle according to one embodiment.

Referring to FIGS. 4 to 6, the display panel 100 may include a substrate 101, a pixel transistor 120, a storage electrode 140, a light-emitting part 150, an encapsulation part 170, a touch part 180, etc. However, the embodiments of the present specification are not limited thereto.

The substrate 101 may provide a space in which various components may be disposed thereon. The substrate 101 may correspond to the flat surface shape of the display panel 100 of FIG. 1. That is, the substrate 101 may include the notch NCP. The substrate 101 may include the display area DA and the non-display area NDA of the display panel 100 in substantially the same manner.

The substrate 101 may include one or more plastic materials, but is not limited thereto, and may include a glass material.

The substrate 101 may be a multi-substrate including a plurality of substrates of a first substrate 101a, a second substrate 101b, and a third substrate 103c each including a plastic material, such as polyimide, but the embodiments of the present specification are not limited thereto. For example, the substrate 101 may be a single substrate formed of a single layer.

The substrate 101 may include a rigid substrate. However, the embodiments of the present specification are not limited thereto, and the substrate 101 may include a flexible substrate.

A buffer layer 102 may be disposed on the substrate 101. The buffer layer 102 can minimize or delay the diffusion of moisture or oxygen penetrating the substrate 101. The buffer layer 102 may be formed by alternately stacking silicon nitride (SiNₓ) and silicon oxide (SiOₓ) at least once, but the embodiments of the present specification are not limited thereto.

The specification describes that the buffer layer 102 is formed as multiple layers formed of three layers, but the number of layers forming the buffer layer 102 is not limited thereto, and the buffer layer 102 may be formed as a single layer.

A light-shielding layer 126 may be disposed on the buffer layer 102. The light-shielding layer 126 can prevent light from transmitting a semiconductor layer 123 of a pixel transistor 120 disposed on the substrate 101 in the display area DA. For example, the semiconductor layer 123 may be disposed to overlap the light-shielding layer 126. The light-shielding layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present specification are not limited thereto.

A first insulating layer 103 may be disposed on the light-shielding layer 126. The first insulating layer 103 can prevent a short circuit between a component of the pixel transistor 120 and the light-shielding layer 126. The first insulating layer 103 may be formed of the same material as the buffer layer 102, but the embodiments of the present specification are not limited thereto. For example, the first insulating layer 103 may be formed of an inorganic material, such as silicon nitride (SiNₓ) or silicon oxide (SiOₓ), but the embodiments of the present specification are not limited thereto.

The pixel transistor 120 may be disposed on the first insulating layer 103. The pixel transistor 120 may include a source electrode 121, a gate electrode 122, the semiconductor layer 123, and a drain electrode 124.

The semiconductor layer 123 may be disposed on the first insulating layer 103. The semiconductor layer 123 may include a metal oxide semiconductor, such as indium-gallium-zinc oxide (IGZO), and a silicon-based semiconductor material, such as amorphous silicon or polycrystalline silicon, but the embodiments of the present specification are not limited thereto. The semiconductor layer 123 may include a source area, a drain area, and a channel area between the source area and the drain area.

Since the polycrystalline semiconductor layer has higher mobility than the amorphous semiconductor layer and the oxide semiconductor layer, power consumption can be less, and reliability can be excellent. Accordingly, a driving transistor may be formed of a polycrystalline semiconductor layer, but the embodiments of the present specification are not limited thereto.

A second insulating layer 104 may be disposed on the semiconductor layer 123. The second insulating layer 104 may be formed of the same material as the first insulating layer 103, but the embodiments of the present specification are not limited thereto. The second insulating layer 104 can prevent a short circuit between the semiconductor layer 123 and another component of the pixel transistor 120.

The gate electrode 122 may be disposed on the second insulating layer 104. The gate electrode 122 may be disposed on the second insulating layer 104 to overlap the channel area of the semiconductor layer 123. The gate electrode 122 may be formed of a single layer or multiple layers made of molybdenum (Mo), copper (Cu), titanium (Ti), aluminum (Al), chromium (Cr), gold (Au), nickel (Ni), neodymium (Nd), or a compound thereof, but the embodiments of the present specification are not limited thereto. The gate electrode 122 may be disposed along with the gate line, but the embodiments of the present specification are not limited thereto.

A third insulating layer 105 may be disposed on the gate electrode 122. The third insulating layer 105 may be formed of the same material as the first insulating layer 103 or the second insulating layer 104, but the embodiments of the present specification are not limited thereto.

The storage electrode 140 may be disposed to be spaced apart from the pixel transistor 120. The storage electrode 140 may include a first storage electrode 141 and a second storage electrode 142.

The first storage electrode 141 may be formed of the same material as the gate electrode 122 and formed on the same layer, but the embodiments of the present specification are not limited thereto.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance. The second storage electrode 142 may be formed of the same material as the first storage electrode 141, but the embodiments of the present specification are not limited thereto.

A fourth insulating layer 106 may be disposed on the second storage electrode 142. The fourth insulating layer 106 may be formed of the same material as the first insulating layer 103, the second insulating layer 104, or the third insulating layer 105, but the embodiments of the present specification are not limited thereto.

The source electrode 121 and the drain electrode 124 may be disposed on the fourth insulating layer 106.

The source electrode 121 and the drain electrode 124 may be electrically connected to the semiconductor layer 123 through contact holes. The source electrode 121 and the drain electrode 124 may be formed of a metallic material. For example, the source electrode 121 and the drain electrode 124 may be formed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The source electrode 121 and the drain electrode 124 may be disposed along with the data line. For example, the data line may be formed of the same material as the source electrode 121 and the drain electrode 124 and formed on the same layer, but the embodiments of the present specification are not limited thereto.

The pixel transistor 120 may be a driving transistor, and although not illustrated, the display panel 100 may further include a switching transistor, but the embodiments of the present specification are not limited thereto.

A first protective layer 111 may be disposed on the source electrode 121 and the drain electrode 124. The first protective layer 111 may be disposed on the pixel transistor 120.

The first protective layer 111 may planarize an upper portion of the pixel transistor 120 and protect the pixel transistor 120. The first protective layer 111 may be formed of an organic material. For example, the first protective layer 111 may be formed of an organic material including an acrylic resin, an epoxy resin, a phenolic resin, a polyamide resin, or a polyimide resin, but the embodiments of the present specification are not limited thereto.

The second protective layer 112 may be disposed on the first protective layer 111. The second protective layer 112 may be formed of the same material as the first protective layer 111, but the embodiments of the present specification are not limited thereto.

A connection electrode 145 may be disposed between the first protective layer 111 and the second protective layer 112.

The connection electrode 145 may be disposed between the pixel transistor 120 and the light-emitting part 150.

The connection electrode 145 may electrically connect the pixel transistor 120 to the light-emitting part 150 between the pixel transistor 120 and the light-emitting part 150. The connection electrode 145 may be formed of the same material as the source electrode 121 and the drain electrode 124, but the embodiments of the present specification are not limited thereto.

The connection electrode 145 may contact the drain electrode 124 through the contact hole formed in the first protective layer 111 and may be electrically connected to the drain electrode 124.

The connection electrode 145 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The light-emitting part 150 may be disposed on the second protective layer 112. The light-emitting part 150 may include the anode electrode 151, an organic layer 152, and the cathode electrode 153.

The anode electrode 151 may be disposed on the second protective layer 112. The anode electrode 151 may be electrically connected to the pixel transistor 120 through a contact hole formed in the first protective layer 111 and the second protective layer 112.

The anode electrode 151 may be a reflective electrode that reflects light, but the embodiments of the present specification are not limited thereto. The anode electrode 151 may include a metallic material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy and may be formed of a single layer or multiple layers, but the embodiments of the present specification are not limited thereto.

For example, the cathode electrode 153 may include a material, such as indium tin oxide (ITO) or indium zinc oxide (IZO), but the embodiments of the present specification are not limited thereto.

The organic layer 152 may be disposed on the anode electrode 151. The organic layer 152 may include one or more light-emitting structures (or light-emitting elements or elements) stacked on the anode electrode 151 in the order or reverse order of a hole transfer layer and an electron transfer layer. For example, the hole transfer layer may include a hole transporting layer, a hole injecting layer, an electron blocking layer, a p-type charge generation layer, etc., but the embodiments of the present specification are not limited thereto. For example, the electron transfer layer may include an electron transporting layer, an electron injecting layer, a hole blocking layer, an n-type charge generation layer, etc., but the embodiments of the present specification are not limited thereto.

The organic layer 152 may be an organic light-emitting layer, an inorganic light-emitting layer, a quantum dot light-emitting layer, a micro light-emitting diode, a micro mini light-emitting diode, etc., but the embodiments of the present specification area not limited thereto. For example, the organic layer 152 of the display panel 100 according to one embodiment of the present specification may include an organic light-emitting layer. The organic layer 152 may be a white light-emitting layer, but the embodiments of the present specification are not limited thereto. The organic layer 152 may be a white light-emitting layer, but the embodiments of the present specification are not limited thereto.

The cathode electrode 153 may be disposed on the organic layer 152. The cathode electrode 153 may be a transparent electrode that transmits light, but the embodiments of the present specification are not limited thereto. For example, the cathode electrode 153 may include a transparent conductive material, such as indium tin oxide (ITO) or indium zinc oxide (IZO), or a metal that transmits visible light, but the embodiments of the present specification are not limited thereto.

A capping layer 156 may be further disposed on the cathode electrode 153. The capping layer 156 can minimize or at least reduce damage to the cathode electrode 153 of the light-emitting element EL and the organic layers 152 located below the cathode electrode 153 from an external light source. The capping layer 156 may be formed of an organic or inorganic film.

The capping layer 156 may be disposed using a material, such as LiF or the like, as an inorganic film and may further include an organic film, but the embodiments of the present specification are not limited thereto. For example, the capping layer 156 may be formed of the stacking structure of an organic film and an inorganic film, and a thickness of the organic film may differ from a thickness of the inorganic film. In this case, the thickness of the organic film may be greater than the thickness of the inorganic film. As another example, the capping layer 156 may be formed of two or more layers by stacking materials having different refractive indexes. Accordingly, it is possible to increase the light efficiency of the display panel 100.

A bank 154 may be disposed to expose the anode electrode 151. The bank 154 may define the opening (or the light-emitting area EA) of the sub-pixel SP and may be disposed to cover an edge of the anode electrode 151. The organic layer 152 may be disposed in the opening of the sub-pixel SP. That is, the organic layer 152 may be disposed on the anode electrode 151 exposed by the bank 154.

The bank 154 may be formed of a material containing black pigment, or an organic material, such as a benzocyclobutene resin, a polyimide resin, an acrylic resin, a photosensitive polymer, etc., but the embodiments of the present specification are not limited thereto. When the bank 154 is formed of a material containing black pigment or black dye, the bank 154 may be an opaque bank. When the bank 154 is formed of a material containing black pigment or black dye, it is possible to shield external light or light reflected from the outside, thereby further increasing the luminance of the display apparatus.

A spacer 155 may be further disposed on the bank 154. The spacer 155 may be formed of the same material as the bank 154, but the embodiments of the present specification are not limited thereto. The spacer 155 can prevent sagging of a mask during a mask process, thereby suppressing or preventing stabbing and scratching defects, etc. of the display panel 100.

The encapsulation part 170 may be disposed on the bank 154 or the light-emitting part 150. The encapsulation part 170 may include one or more insulating layers. For example, the encapsulation part 170 may include a first inorganic encapsulation layer 171, an organic encapsulation layer 172 formed on the first inorganic encapsulation layer 171, and a second inorganic encapsulation layer 173 formed on the organic encapsulation layer 172. The encapsulation part 170 may include one or more inorganic layers and one or more organic layers. For example, the first inorganic encapsulation layer 171 and the second inorganic encapsulation layer 173 may include an inorganic material, and the organic encapsulation layer 172 may include an organic material, but the embodiments of the present specification are not limited thereto.

The organic encapsulation layer 172 may be ended inside the dam part DMP. That is, the organic encapsulation layer 172 may be disposed inside an area surrounded by the dam part DMP without extending beyond the dam part DMP.

The touch part 180 may be disposed on the encapsulation part 170. The touch part 180 may include a touch buffer layer 181, a first touch electrode 182, a first touch insulating layer 183, a black matrix BM, a second touch insulating layer 184, a second touch electrode 185, and a third touch insulating layer 186.

The touch buffer layer 181 may be disposed on the encapsulation part 170. For example, the touch buffer layer 181 may be disposed on the second inorganic encapsulation layer 173. The touch buffer layer 181 may be formed of the same material as the buffer layer 102, but the embodiments of the present specification are not limited thereto.

The first touch electrode 182 may be disposed on the touch buffer layer 181.

The first touch insulating layer 183 may be disposed on the first touch electrode 182. The first touch insulating layer 183 may be formed of silicon oxide (SiOₓ), silicon nitride (SiNₓ), or multiple layers thereof, but the embodiments of the present specification are not limited thereto.

The black matrix BM may be disposed on the first touch insulating layer 183. The black matrix BM may include materials capable of absorbing light. The black matrix BM may include a black pigment or dye, but is not limited thereto. The black matrix BM can prevent a light leakage defect, etc. that may occur between the sub-pixels SP.

The second touch insulating layer 184 may be disposed on the black matrix BM. The second touch insulating layer 184 may include an organic insulation material. For example, the second touch insulating layer 184 may be formed of photo acryl, benzocyclobutene (BCB), polyimide (PI), or polyamide (PA), but is not limited thereto.

The second touch electrode 185 may be disposed on the second touch insulation layer 184. The second touch electrode 185 may include a la touch electrode 185a extending in the first direction DR1 and a 1b touch electrode 185b extending in the second direction DR2 different from the first direction.

The first touch electrode 182 may be electrically connected to a 2a touch electrode 185a through a contact hole formed in the second touch insulating layer 184. For example, the 2a touch electrode 185a and the first touch electrode 182 may extend in the first direction DR1.

The first touch electrode 182 and the second touch electrode 185 may include a metallic material. For example, the sensor electrode 185 and the bridge electrode 182 may be formed of titanium (Ti), nickel (Ni), aluminum (Al), or an alloy thereof and formed of a triple layer, such as titanium (Ti)/aluminum (Al)/titanium (Ti), but the embodiments of the present specification are not limited thereto.

One of the first touch electrode 182 and the second touch electrode 185 may include a function of detecting touch, and the other may include a function of driving touch, but the embodiments of the present specification are not limited thereto.

The third touch insulating layer 186 may be disposed on the second touch electrode 185. The third touch insulating layer 186 may be formed of the same material as the first touch insulating layer 183, but is not limited thereto.

The microlens ML may be disposed on the third touch insulating layer 186. The microlens ML may include a hemispherical or semi-cylindrical shape, but is not limited thereto. The shape of the microlens ML may vary according to the size, shape, etc. of the light-emitting area EA.

In addition, by arranging the microlens ML, it is possible to secure a wide viewing angle characteristic, increase luminance, and prevent or reduce light leakage by shielding leaked light, reflected light, etc.

The center of the microlens ML and the center of the light-emitting area EA corresponding thereto may be misaligned. However, since some components of the light-emitting part 150 may be tilted, light emitted from the light-emitting area EA may travel to the microlens ML.

A lens protective film 190 may be disposed on the microlens ML. The lens protective film 190 may include an organic insulation material, but is not limited thereto. The lens protective film 190 may protect the microlens ML by covering the microlens ML.

A refractive index of the lens protective film 190 may be smaller than a refractive index of the microlens ML. Accordingly, due to a difference in refractive indexes between the microlens ML and the lens protective film 190, light that has passed through the microlens ML can be prevented from being reflected toward the substrate 101.

In the area in which the light-emitting part 150 is disposed, a part of an upper surface of the second protective layer 112 may be formed to have inclination. The light-emitting part 150 may be disposed on the second protective layer 112 of which at least a part is inclined. At least a part of each of the anode electrode 151 and the organic layer 152 that are disposed on the inclined second protective layer 112 may be tilted.

The at least a part of each of the anode electrode 151 and the organic layer 152 may be tilted toward the microlens ML. Accordingly, light emitted from the light-emitting area EA may travel toward the microlens ML.

Specifically, each of the anode electrode 151 and the organic layer 152 may be disposed on the second protective layer 112 of which at least a part is inclined. Each of the anode electrode 151 and the organic layer 152 may be disposed on the second protective layer 112 of which the entire area is inclined, but is not limited thereto.

The anode electrode 151 and the organic layer 152 that are disposed on the inclined second protective layer 112 may be disposed to be inclined (tilted) corresponding to the inclined second protective layer 112. Accordingly, a part of the cathode electrode 153 disposed on the organic layer 152 may be disposed to be inclined.

For example, the anode electrode 151 and the organic layer 152 may be disposed to be inclined in a thickness direction (a third direction DR3) of the display panel 100 in the 1_1 light-emitting area EA1_1, the 2_1 light-emitting area EA2_1, and surrounding areas thereof. That is, a direction in which the upper surface of the anode electrode 151 and the upper surface of the organic layer 152 face may be inclined in the thickness direction (the third direction DR3) of the display panel 100.

In the 1-1 light-emitting area EA1_1, the 2-1 light-emitting area EA2_1, and peripheries thereof, directions in the anode electrode 151 and the organic layer 152 are tilted may be different.

In FIG. 5, the anode electrode 151 and the organic layer 152 around the 1_1 light-emitting area EA1_1 of the 1_1 sub-pixel SP1_1 and the 2_1 light-emitting area EA2_1 of the 2_1 sub-pixel SP2_1 have been described, but the descriptions thereof may be applied to all of the sub-pixels SP.

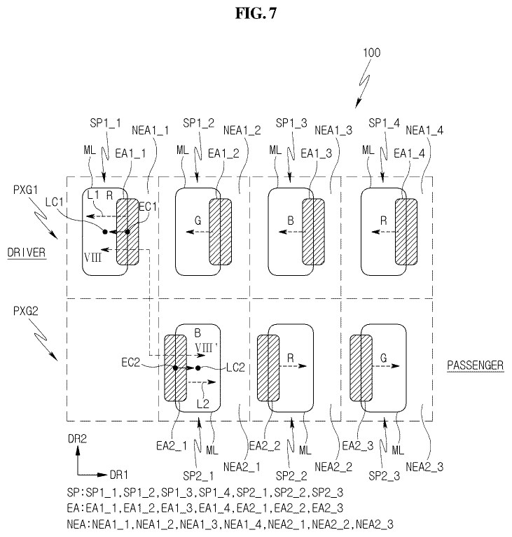

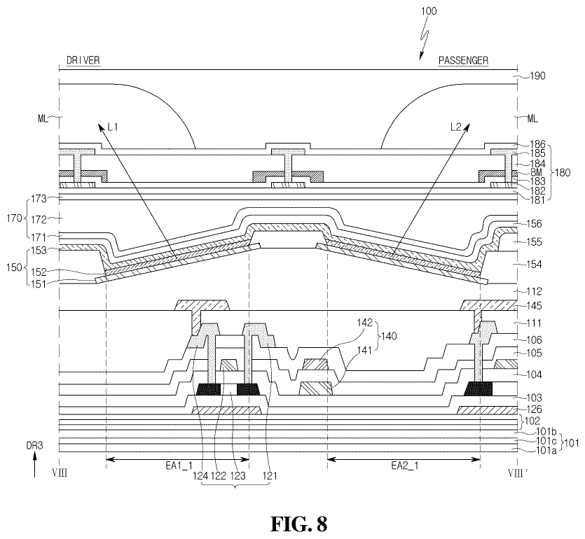

Accordingly, light emitted from each sub-pixel SP may be inclined in the thickness direction (the third direction DR3) of the display panel 100. The description thereof will be given with reference to FIGS. 7 and 8.

FIG. 7 is a plan view of a display panel according to one embodiment. FIG. 8 is a cross-sectional view along line VIII-VIII′ in FIG. 7 according to one embodiment. FIGS. 7 and 8 are schematic views that are substantially the same as FIGS. 4 and 5, respectively, but illustrate paths of light L1 and L2 emitted from the light-emitting part 150.

Referring to FIGS. 7 and 8, the microlens ML and the light-emitting area EA corresponding thereto may be misaligned. Specifically, a center of the microlens ML and a center of the light-emitting area EA may be misaligned.

A center EC1 of the 1_1 light-emitting area EA1_1 of the 1_1 sub-pixel SP1_1 and a center LC1 of the microlens ML disposed on the 1_1 sub-pixel SP1_1 may be misaligned. In a plan view, the center LC1 of the microlens ML may be misaligned from the center EC1 of the 1_1 light-emitting area EA1_1 to the other side (left side in a plan view) in the first direction DR1.

The description of the misalignment of the 1_1 sub-pixel SP1_1 may be applied to the remaining sub-pixels SP1_2, SP1_3, and SP1_4 of the first pixel group PXG1 in the substantially the same manner. However, in each of the sub-pixels SP1_1, SP1_2, SP1_3, and SP1_4 of the first pixel group PXG1, the degree of misalignment between the microlens ML and the light-emitting area EA may be different.

However, the embodiments of the present specification are not limited thereto, and a direction in which the center LCI of the microlens ML and the center EC1 of the 1_1 light-emitting area EA1_1 are misaligned may vary according to a design.

A center EC2 of the 2_1 light-emitting area EA2_1 of the 2_1 sub-pixel SP2_1 and a center LC2 of the microlens ML disposed on the 2_1 sub-pixel SP2_1 may be misaligned. In a plan view, the center LC2 of the microlens ML may be misaligned from the center EC2 of the 2_1 light-emitting area EA2_1 to one side (right side in a plan view) in the first direction DR1.

The description of the misalignment of the 2_1 sub-pixel SP2_1 may be applied to the remaining sub-pixels SP2_2 and SP2_3 of the second pixel group PXG2 in the substantially the same manner. However, in each of the sub-pixels SP2_1, SP2_2, and SP2_3 of the second pixel group PXG2, the degree of misalignment between the microlens ML and the light-emitting area EA may be different.

However, the embodiments of the present specification are not limited thereto, and a direction in which the center LC2 of the microlens ML and the center EC2 of the 2_1 light-emitting area EA2_1 are misaligned may vary according to a design.

The opening (or the light-emitting area EA) of the sub-pixel SP and the light-emitting part 150 disposed around the opening may be disposed to be tilted with respect to the thickness direction (the third direction DR3), and the light L1 and L2 emitted from the light-emitting part 150 may travel in a direction tilted with respect to the thickness direction (the third direction DR3).

As the microlens ML and the light-emitting area EA are misaligned, even when the light L1 and L2 emitted from the light-emitting part 150 travels while being tilted with respect to the thickness direction (the third direction DR3), each light L1 or L2 may travel toward the microlens ML.

The sub-pixels SP1_1, SP1_2, SP1_3, and SP1_4 disposed in the first pixel group PXG1 may emit the light L1 to the left (the other side in the first direction DR1) in a plan view. The sub-pixels SP2_1, SP2_2, and SP2_3 disposed in the second pixel group PXG2 may emit the light L2 to the right (one side in the first direction DR1) in a plan view.

That is, the light L1 emitted from the sub-pixels SP1_1, SP1_2, SP1_3, and SP1_4 of the first pixel group PXG1 may travel while tilted to the other side in the first direction DR1 with respect to the thickness direction (the third direction DR3). The light L2 emitted from the sub-pixels SP2_1, SP2_2, and SP2_3 of the second pixel group PXG2 may travel while tilted to one side in the first direction DR1 with respect to the thickness direction (the third direction DR3).

The direction and degree of misalignment of the microlens ML and the light-emitting area EA may vary according to the traveling direction of the light emitted from the sub-pixels SP of each pixel group PXG1 or PXG2.

In a plan view, the sub-pixels SP1_1, SP1_2, SP1_3, and SP1_4 disposed in the first pixel group PXG1 and the sub-pixels SP2_1, SP2_2, and SP2_3 disposed in the second pixel group PXG2 may emit light in different directions, and thus a screen displayed to a driver DRIVER sitting in the driver's seat may be distinguished from a screen displayed to a passenger PASSENGER sitting in the passenger's seat so that each may be controlled separately, and different screens may be displayed to the driver DRIVER and the passenger PASSENGER.

Hereinafter, a cross-sectional structure of the non-display area NDA of the display apparatus 1 will be described. The same content as that described in the cross-sectional structure of the display area DA will be briefly described or omitted.

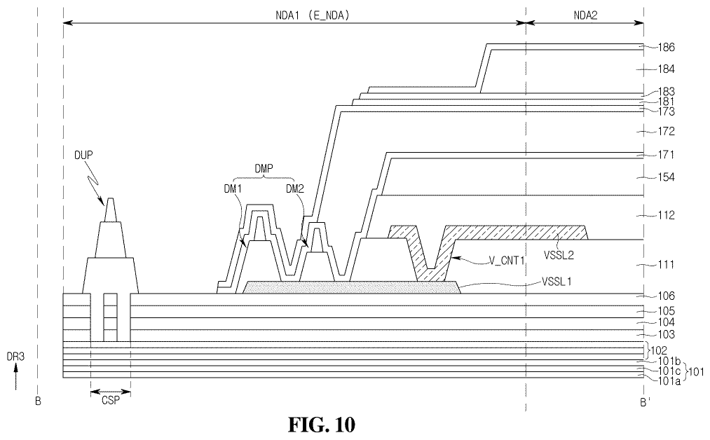

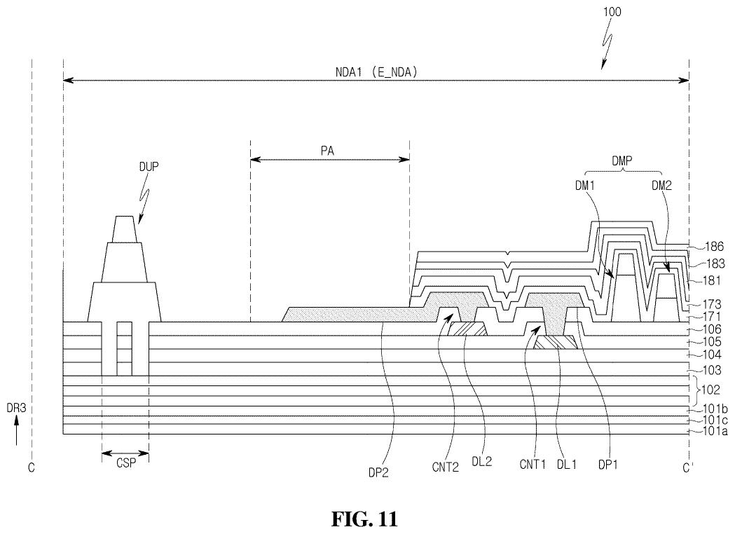

FIG. 9 is a cross-sectional view along line A-A′ in FIG. 1 according to one embodiment. FIG. 10 is a cross-sectional view along line B-B′ in FIG. 3 according to one embodiment. FIG. 11 is a cross-sectional view along line C-C′ in FIG. 3 according to one embodiment.

FIG. 9 illustrates a cross-sectional structure of the second non-display area NDA2. FIGS. 10 and 11 illustrate cross-sectional structures of the first non-display area NDA1. FIGS. 10 and 11 illustrate cross sections of the notch non-display area N_NDA of the first non-display area NDA1, but the descriptions thereof may also be applied to the extension non-display area E_NDA in substantially the same manner.

Referring to FIGS. 1, 3, 5, and 9 to 11, in the display area DA and the second non-display area NDA2, the display panel 100 may include the substrate 101, the buffer layer 102, the first insulating layer 103, the second insulating layer 104, the third insulating layer 105, the fourth insulating layer 106, the first protective layer 111, the second protective layer 112, the bank 154, the encapsulation part 170, the touch buffer layer 181, the first touch insulating layer 183, and the third touch insulating layer 186 that are sequentially disposed.

In the second non-display area NDA2, the display panel 100 may further include the gate control transistor G120, the low-potential voltage line VSSL, the dam part DMP, a plurality of pads VSSP, VDDP, and DP disposed in the pad area PA, the data line DL (DL1 and DL2), and a crack prevention pattern CSP.

The gate control transistor G120 may have substantially the same configuration as the pixel transistor 120 of the sub-pixel SP and may be formed together by the same process as the pixel transistor 120 of the sub-pixel SP, but is not limited thereto.

The gate control transistor G120 may include a control source electrode G121, a control gate electrode G122, a control semiconductor layer G123, and a control drain electrode G124.

The light-shielding layer 126 may be further disposed under the gate control transistor G120. One of the control source electrode G121 and the control drain electrode G124 may be electrically connected in contact with the light-shielding layer 126, but is not limited thereto.

The low-potential voltage line VSSL may include the first low-potential voltage line VSSL1 and the second low-potential voltage line VSSL2 that are disposed on different layers. The first low-potential voltage line VSSL1 and the second low-potential voltage line VSSL2 may be disposed on different layers and electrically connected through a first low-potential contact hole V_CNT1.

The first low-potential voltage line VSSL1 and the second low-potential voltage line VSSL2 may be formed of different conductive layers. For example, the first low-potential voltage line VSSL1 may be formed of a first conductive layer, and the second low-potential voltage line VSSL2 may be formed of a second conductive layer different from the first conductive layer. The first low-potential voltage line VSSL1 may be formed of a first conductive layer including the source electrode 121 and the drain electrode 124. The second low-potential voltage line VSSL2 may be formed of a second conductive layer including the connection electrode 145.

That is, the first conductive layer may include the first low-potential voltage line VSSL1, the source electrode 121, and the drain electrode 124, and the second conductive layer may include the second low-potential voltage line VSSL2 and the connection electrode 145. The first low-potential voltage line VSSL1 may be formed of the same first conductive layer as the source electrode 121 and the drain electrode 124, and the connection electrode 145 may be formed of the same second conductive layer as the second low-potential voltage line VSSL2. The first conductive layer may be disposed on the fourth insulating layer 106, and the second conductive layer may be disposed on the first protective layer 111.

The first conductive layer may further include the gate control source electrode G121 and the gate control drain electrode G124. That is, the gate control source electrode G121 and the gate control drain electrode G124 may be formed of the same conductive layer as the first low-potential voltage line VSSL1.

The low-potential voltage line VSSL1 may be disposed on the fourth insulating layer 106. The first protective layer 111 may be disposed on the first low-potential voltage line VSSL1. The first low-potential voltage pad VSSL1 may be disposed on the same layer as the source electrode 121 and the drain electrode 124, may include the same material as the source electrode 121 and the drain electrode 124, and may be formed together using one mask by the same process as the source electrode 121 and the drain electrode 124, but is not limited thereto.

The second low-potential voltage line VSSL2 may be disposed on the first insulating layer 111. The second protective layer 112 may be disposed on the second low-potential voltage line VSSL2. The second low-potential voltage pad VSSL2 may be disposed on the same layer as the connection electrode 145, may include the same material as the connection electrode 145, and may be formed together using one mask by the same process as the connection electrode 145, but is not limited thereto.

The first low-potential voltage line VSSL1 and the second low-potential voltage line VSSL2 may be electrically connected in contact with each other through the first low-potential contact hole V_CNT1 in an overlapping area. The first low-potential contact hole V_CNT1 may be defined by passing through the first protective layer 111 in an area in which the first low-potential voltage line VSSL1 and the second low-potential voltage line VSSL2 overlap each other and may expose the first low-potential voltage line VSSL1.

The first low-potential contact hole V_CNT1 is illustrated as being disposed in the first non-display area NDA1, but is not limited thereto, and the first low-potential contact hole V_CNT1 may be disposed in the second non-display area NDA2.

The display panel 100 may further include a low-potential connection electrode CE. The low-potential connection electrode CE may be disposed on the second protective layer 112. The bank 154 may be disposed on the low-potential connection electrode CE. The low-potential connection electrode CE may be disposed on the same layer as the anode electrode 151 and may include the same material as the anode electrode 151, and the low-potential connection electrode CE and the anode electrode 151 may be formed together using one mask by the same process, but the embodiments of the present specification are not limited thereto.

The low-potential connection electrode CE may be formed of the same third conductive layer as the anode electrode 151. The third conductive layer may differ from the first conductive layer and the second conductive layer. That is, the third conductive layer may include the low-potential connection electrode CE and the anode electrode 151.

The second low-potential voltage line VSSL2 and the low-potential connection electrode CE may be electrically connected in contact with each other through a second low-potential contact hole V_CNT2 in an overlapping area. The second low-potential contact hole V_CNT2 may be defined by passing through the second protective layer 112 in an area in which the second low-potential voltage line VSSL2 and the low-potential connection electrode CE overlap each other and may expose the second low-potential voltage line VSSL2.

The low-potential connection electrode CE may be electrically connected to the cathode electrode 153. The low-potential connection electrode CE and the cathode electrode 153 may be electrically connected in contact with each other through a third low-potential contact hole V_CNT3 in an overlapping area. The third low-potential contact hole V_CNT3 may be defined by passing through the bank 154 in an area in which the low-potential connection electrode CE and the cathode electrode 153 overlap each other and may expose the low-potential connection electrode CE.

Through the low-potential connection electrode CE, the second low-potential voltage line VSSL2 may be electrically connected to the cathode electrode 153. Furthermore, through the low-potential connection electrode CE, the low-potential voltage line VSSL may be electrically connected to the cathode electrode 153.

Through the low-potential connection electrode CE and the second low-potential voltage line VSSL2, the first low-potential voltage line VSSL1 may be electrically connected to the cathode electrode 153.

The second low-potential voltage line VSSL2 may overlap the gate driving unit GIP. The second low-potential voltage line VSSL2 may overlap the gate driving unit GIP in the thickness direction (the third direction DR3).

The second low-potential voltage line VSSL2 may overlap the gate control transistor G120. The second low-potential voltage line VSSL2 may overlap the gate control transistor G120 in the thickness direction (the third direction DR3).

The second low-potential voltage line VSSL2 may overlap at least one of the control source electrode G121, the control gate electrode G122, the control semiconductor layer G123, and the control drain electrode G124 that constitute the gate control transistor G120 in the thickness direction (the third direction DR3).

Accordingly, the area of the second low-potential voltage line VSSL2 and the area of the gate driving unit GIP in the second non-display area NDA2 may overlap each other, and the area of the second non-display area NDA2 can be reduced. That is, the bezel area of the display apparatus 1 can be reduced, and higher aesthetic feeling and use convenience can be provided to a user.

Furthermore, since a separate additional mask for arranging the first low-potential voltage line VSSL1 and the second low-potential voltage line VSSL2 is not required, it is possible to optimize the process, thereby suppressing or preventing an increase in production energy.

The dam part DMP may include a first dam DM1 and a second dam DM2. The first dam DM1 and the second dam DM2 may overlap a first low-potential voltage line VSSL1 or a second low-potential voltage line VSSL2.

In the first non-display area NDA1, the first dam DM1 and the second dam DM2 may overlap the first low-potential voltage line VSSL1. In the second non-display area NDA2, the first dam DM1 and the second dam DM2 may overlap the second low-potential voltage line VSSL2.

The first dam DM1 may be disposed outside the second dam DM2, but is not limited thereto.

The first dam DM1 may be formed in a multilayered structure. Each layer of the first dam DM1 may include the same material as the second protective layer 112 and the bank 154, and each layer of the first dam DM1, the second protective layer 112, and the bank 154 may be formed together using one mask by the same process, but the embodiments of the present specification are not limited thereto.

The second dam DM2 may be formed in a multilayered structure. Each layer of the second dam DM2 may include the same material as the bank 154 and the spacer 155, and each layer of the second dam DM2, the bank 154, and the spacer 155 may be formed together using one mask by the same process, but the embodiments of the present specification are not limited thereto.

The crack prevention pattern CSP may be disposed at an outermost edge of the non-display area NDA. The crack prevention pattern CSP may be defined by recessing at least one of the inorganic films disposed on the substrate 101.

For example, the crack protection pattern CSP may be defined by recessing the first insulating layer 103, the second insulating layer 104, the third insulating layer 105, and the fourth insulating layer 106, but is not limited thereto.

A crack dummy pattern DUP may be further disposed on the crack protection pattern CSP. The crack dummy pattern DUP may fill the recessed crack protection pattern CSP. The crack dummy pattern DUP may be formed of multiple layers. For example, the crack dummy pattern DUP may be formed of three layers. Layers of the crack dummy pattern DUP may include the same material as the first protective layer 111, the second protective layer 112, and the bank 154.

Although not illustrated, the high-potential voltage line VDDL may be disposed on the buffer layer 102 and covered by the first insulating layer 103. The high-potential voltage line VDDL may include the same material as the light-shielding layer 126, and the high-potential voltage line VDDL and the light-shielding layer 126 may be formed together using one mask by the same process, but the embodiments of the present specification are not limited thereto.

Although not illustrated, the high-potential voltage pad VDDP may be disposed on the same layer as the source electrode 121 and the drain electrode 124, may include the same material as the source electrode 121 and the drain electrode 124, and may be formed together using one mask by the same process as the source electrode 121 and the drain electrode 124, but is not limited thereto.

In this case, the high-potential voltage pad VDDP may be electrically connected in contact with the high-potential voltage line VDDL through the high-potential contact hole S_CNT that exposes the high-potential voltage line VDDL.

However, the embodiments of the present specification are not limited thereto, and the high-potential voltage line VDDL may be disposed on the same layer as the source electrode 121 and the drain electrode 124 and may include the same material as the source electrode 121 and the drain electrode 124, and the high-potential voltage line VDDL, the source electrode 121, and the drain electrode 124 may be formed together using one mask by the same process.

The first data pad DP1 and the second data pad DP2 may be disposed on the fourth insulating layer 106. The first data pad DP1 and the second data pad DP2 may be disposed on the same layer as the source electrode 121 and the drain electrode 124, may include the same material as the source electrode 121 and the drain electrode 124, and may be formed together using one mask by the same process as the source electrode 121 and the drain electrode 124, but are not limited thereto.

The first data line DL1 may be disposed on the second insulating layer 104 and covered by the third insulating layer 105. The first data line DL1 may include the same material as the gate electrode 122 and may be formed together using one mask by the same process as the gate electrode 122, but is not limited thereto.

The second data line DL2 may be disposed on the third insulating layer 105 and covered by the fourth insulating layer 106. The second data line DL2 may include the same material as the second storage electrode 142 and may be formed together using one mask by the same process as the second storage electrode 142, but is not limited thereto.

The first data line DL1 may be electrically connected in contact with the first data pad DP1 through the first data contact hole CNT1. The second data line DL2 may be electrically connected in contact with the second data pad DP2 through the second data contact hole CNT2.

The crack prevention pattern CSP may be disposed outside the pad area PA. The crack prevention pattern CSP may be disposed between ends of the pad area PA and the first non-display area NDA1.

However, the plurality of pads VSSP, VDDP, and DP may not be covered by a plurality of inorganic films. The plurality of inorganic films disposed on the fourth insulating layer 106 may expose the plurality of pads VSSP, VDDP, and DP. The plurality of inorganic films disposed on the fourth insulating layer 106 may not be disposed in the pad area PA.

Accordingly, the flexible film COF may be configured so that at least a part thereof is disposed to overlap the pad area PA and attached to the display panel 100, and the flexible film COF may be electrically connected in contact with the plurality of pads VSSP, VDDP, and DP of the pad area PA.

A display apparatus according to various embodiments of the present specification may be described as follows.

According to embodiments of the present specification, there is provided a display apparatus including a substrate including a display area and a non-display area disposed around the display area, a light-emitting part disposed on the substrate in the display area, a pixel transistor disposed on the substrate in the display area, a gate driving unit disposed on the substrate in the non-display area and connected to the pixel transistor, and a low-potential voltage line disposed on the substrate in the non-display area and connected to the light-emitting part, in which the gate driving unit and the low-potential voltage line overlap each other in the non-display area.

According to various embodiments of the present specification, the low-potential voltage line may include a first low-potential voltage line formed of a first conductive layer, and a second low-potential voltage line formed of a second conductive layer different from the first conductive layer.

According to various embodiments of the present specification, the first low-potential voltage line and the second low-potential voltage line may contact each other through a first low-potential contact hole in an overlapping area in which the first low-potential voltage line and the second low-potential voltage line overlap with each other.

According to various embodiments of the present specification, the display apparatus may further include a first protective layer disposed on the pixel transistor, in which the pixel transistor may include a source electrode, a gate electrode, a semiconductor layer, and a drain electrode, the first low-potential voltage line may be formed of the same first conductive layer as the source electrode and the drain electrode, and the second low-potential voltage line may be disposed on the first protective layer.

According to various embodiments of the present specification, the display apparatus may further include a second protective layer disposed on the second low-potential voltage line, a low-potential connection electrode disposed on the second protective layer, and a bank disposed on the low-potential connection electrode, in which the second low-potential voltage line and the low-potential connection electrode may come into contact with through a second low-potential contact hole, and the low-potential connection electrode may be electrically connected to the light-emitting part.

According to various embodiments of the present specification, the light-emitting part may include an anode electrode disposed on the second protective layer, an organic layer disposed on the anode electrode, and a cathode electrode disposed on the organic layer, and the low-potential connection electrode may contact the cathode electrode through a third low-potential contact hole.

According to various embodiments of the present specification, the low-potential connection electrode may be formed of the same third conductive layer as the anode electrode, and the third conductive layer may differ from the first conductive layer and the second conductive layer.

According to various embodiments of the present specification, the display apparatus may further include a connection electrode disposed on the first protective layer, in which the connection electrode may be disposed between the pixel transistor and the light-emitting part, and the connection electrode may be formed of the same second conductive layer as the second low-potential voltage line.

According to various embodiments of the present specification, the display apparatus may further include a second protective layer disposed on the connection electrode, in which the light-emitting part may include an anode electrode disposed on the second protective layer, an organic layer disposed on the anode electrode, and a cathode electrode disposed on the organic layer, and the connection electrode may come into contact with the anode electrode through a contact hole passing through the second protective layer.

According to various embodiments of the present specification, the low-potential voltage line may include a first low-potential voltage line and a second low-potential voltage line, wherein the low-potential voltage line further comprises a first protective layer disposed between the first low-potential voltage line and the second low-potential voltage line, and the gate driving unit may overlap the second low-potential voltage line.

According to various embodiments of the present specification, the gate driving unit may include at least one gate control transistor, and the gate control transistor may overlap the second low-potential voltage line.

According to various embodiments of the present specification, the gate control transistor may include a gate control source electrode and a gate control drain electrode, and the gate control source electrode and the gate control drain electrode may be formed of the same conductive layer as the first low-potential voltage line.

According to various embodiments of the present specification, the display apparatus may further include a pad area disposed in the non-display area, in which the non-display area may include a first non-display area disposed under the display area, and a second non-display area disposed at left, right, and upper sides of the display area, the pad area may be disposed in the first non-display area, and the low-potential voltage line may include a first low-potential voltage line disposed in the first non-display area, and a second low-potential voltage line disposed in the second non-display area.

According to various embodiments of the present specification, the display apparatus may further include a first protective layer disposed between the first low-potential voltage line and the second low-potential voltage line, in which the first low-potential voltage line and the second low-potential voltage line may come into contact with each other through a contact hole defined by passing through the first protective layer, and the first low-potential voltage line and the second low-potential voltage line may be disposed to surround the display area.

According to embodiments of the present specification, there is provided a display apparatus including a substrate including a display area in which a plurality of sub-pixels are disposed, and a non-display area disposed around the display area, a low-potential voltage line disposed in the non-display area, and a pad area disposed in the non-display area, in which the non-display area includes a first non-display area disposed under the display area, and a second non-display area disposed at left, right, and upper sides of the display area, and the low-potential voltage line includes a first low-potential voltage line formed of a first conductive layer and disposed in the first non-display area, and a second low-potential voltage line formed of a second conductive layer different from the first conductive layer and disposed in the second non-display area.

According to various embodiments of the present specification, the display apparatus may further include a gate driving unit disposed in the second non-display area, in which the second low-potential voltage line may overlap the gate driving unit.

According to various embodiments of the present specification, the display apparatus may further include a pixel transistor disposed in the display area and electrically connected to the gate driving unit, and a light-emitting part disposed in the display area and electrically connected to the low-potential voltage line.

According to various embodiments of the present specification, the display apparatus may further include a first protective layer disposed on the pixel transistor, in which the pixel transistor may include a source electrode, a gate electrode, a semiconductor layer, and a drain electrode, the first low- potential voltage line may be formed of the same first conductive layer as the source electrode and the drain electrode, and the second low-potential voltage line may be disposed on the first protective layer.

According to various embodiments of the present specification, the display apparatus may further include a connection electrode disposed on the first protective layer, in which the connection electrode may be disposed between the pixel transistor and the light-emitting part, and the connection electrode may be formed of the same second conductive layer as the second low-potential voltage line.

According to various embodiments of the present specification, the display apparatus may further include a first protective layer disposed between the first low-potential voltage line and the second low-potential voltage line, in which the first low-potential voltage line and the second low-potential voltage line may come into contact with each other through a contact hole defined by passing through the first protective layer, and the first low-potential voltage line and the second low-potential voltage line may be disposed to surround the display area.

Although the embodiments have been described above with reference to the accompanying drawings, those skilled in the art to which the present specification pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### DESCRIPTION OF REFERENCE NUMERALS

1: display apparatus

100: display apparatus

VSSL: low-potential voltage line

VSSL1: first low-potential voltage line

VSSL2: second low-potential voltage line

GIP: gate driving unit

NCP: notch

DA: display area

NDA: non-display area

NDA1: first non-display area

NDA2: second non-display arca

N_NDA: notch non-display area

E_NDA: extension non-display arca

PA: pad arca

SP: sub-pixel

EA: light-emitting arca

NEA: non-light-emitting area

ML: microlens

What is claimed is:

1. A display apparatus comprising:
a substrate including a display area and a non-display area disposed around the display area;
a light-emitting part on the substrate in the display area;
a gate pixel on the substrate in the display area;
a pixel transistor on the substrate in the display area,
a gate driving circuit on the substrate in the non-display area, the gate driving circuit connected to the pixel transistor; and
a low-potential voltage line on the substrate in the non-display area, the low-potential voltage line connected to the light-emitting part,
wherein the gate driving circuit and the low-potential voltage line overlap each other in the non-display area.

2. The display apparatus of claim 1, wherein the low-potential voltage line comprises:
a first low-potential voltage line that includes a first conductive layer; and
a second low-potential voltage line that includes a second conductive layer that is different from the first conductive layer.

3. The display apparatus of claim 2, wherein the first low-potential voltage line and the second low-potential voltage line contact each other through a first low-potential contact hole in an overlapping area in which the first low-potential voltage line and the second low-potential voltage line overlap with each other.

4. The display apparatus of claim 3, further comprising:
a first protective layer on the pixel transistor,
wherein the pixel transistor includes a source electrode, a gate electrode, a semiconductor layer, and a drain electrode,
wherein the first low-potential voltage line includes a same first conductive layer as the source electrode and the drain electrode, and
wherein the second low-potential voltage line is on the first protective layer.

5. The display apparatus of claim 4, further comprising:
a second protective layer on the second low-potential voltage line;
a low-potential connection electrode on the second protective layer, and
a bank on the low-potential connection electrode,
wherein the second low-potential voltage line and the low-potential connection electrode contact each other through a second low-potential contact hole, and the low-potential connection electrode is electrically connected to the light-emitting part.

6. The display apparatus of claim 5, wherein the light-emitting part includes an anode electrode on the second protective layer, an organic layer on the anode electrode, and a cathode electrode on the organic layer, and
wherein the low-potential connection electrode and the cathode electrode contact each other through a third low-potential contact hole.

7. The display apparatus of claim 6, wherein the low-potential connection electrode includes a same third conductive layer as the anode electrode and the third conductive layer differs from the first conductive layer and the second conductive layer.

8. The display apparatus of claim 4, further comprising:
a connection electrode on the first protective layer, the connection electrode between the pixel transistor and the light-emitting part,
wherein the connection electrode includes a same second conductive layer as the second low-potential voltage line.

9. The display apparatus of claim 8, further comprising:
a second protective layer on the connection electrode,
wherein the light-emitting part includes an anode electrode on the second protective layer, an organic layer on the anode electrode, and a cathode electrode on the organic layer, and
wherein the connection electrode contacts the anode electrode through a contact hole passing through the second protective layer.

10. The display apparatus of claim 1, wherein the low-potential voltage line includes a first low-potential voltage line and a second low-potential voltage line, the display apparatus further comprising:
a first protective layer between the first low-potential voltage line and the second low-potential voltage line,
wherein the gate driving circuit overlaps the second low-potential voltage line.

11. The display apparatus of claim 10, wherein the gate driving circuit includes at least one gate control transistor that overlaps the second low-potential voltage line.

12. The display apparatus of claim 11, wherein the at least one gate control transistor includes a gate control source electrode and a gate control drain electrode, and
wherein the gate control source electrode and the gate control drain electrode include a same conductive layer as the first low-potential voltage line.

13. The display apparatus of claim 1, further comprising:
a pad area in the non-display area,
wherein the non-display area includes a first non-display area under the display area and a second non-display area disposed at a left side, a right side, and an upper side of the display area,
wherein the pad area is in the first non-display area, and
wherein the low-potential voltage line includes a first low-potential voltage line in the first non-display area and a second low-potential voltage line in the second non-display area.

14. The display apparatus of claim 13, further comprising:
a first protective layer between the first low-potential voltage line and the second low-potential voltage line,
wherein the first low-potential voltage line and the second low-potential voltage line contact each other through a contact hole that passes through the first protective layer, and
wherein the first low-potential voltage line and the second low-potential voltage line surround the display area.

15. A display apparatus comprising:
a substrate including a display area in which a plurality of sub-pixels are disposed and a non-display area disposed around the display area;
a low-potential voltage line in the non-display area; and
a pad area in the non-display area,
wherein the non-display area includes a first non-display area under the display area and a second non-display area disposed at a left side, a right side, and an upper side of the display area, and
wherein the low-potential voltage line includes:
a first low-potential voltage line including a first conductive layer and disposed in the first non-display area; and
a second low-potential voltage line including a second conductive layer that is different from the first conductive layer and disposed in the second non-display area.

16. The display apparatus of claim 15, further comprising:
a gate driving circuit in the second non-display area,
wherein the second low-potential voltage line overlaps the gate driving circuit.

17. The display apparatus of claim 16, further comprising:
a pixel transistor in the display area, the pixel transistor electrically connected to the gate driving circuit; and
a light-emitting part in the display area, the light-emitting part electrically connected to the low-potential voltage line.

18. The display apparatus of claim 17, further comprising:
a first protective layer on the pixel transistor,
wherein the pixel transistor includes a source electrode, a gate electrode, a semiconductor layer, and a drain electrode,
wherein the first low-potential voltage line includes a same first conductive layer as the source electrode and the drain electrode, and
wherein the second low-potential voltage line is on the first protective layer.

19. The display apparatus of claim 18, further comprising:
a connection electrode on the first protective layer, the connection electrode between the pixel transistor and the light-emitting part, and
wherein the connection electrode includes a same second conductive layer as the second low-potential voltage line.

20. The display apparatus of claim 15, further comprising:
a first protective layer between the first low-potential voltage line and the second low-potential voltage line,
wherein the first low-potential voltage line and the second low-potential voltage line contact each other through a contact hole that passes through the first protective layer, and
wherein the first low-potential voltage line and the second low-potential voltage line surround the display area.
